(19) United States
(12) Patent Application Publication
(10) Pub. No.: US 2024/0393153 A1
(43) Pub. Date: Nov. 28, 2024

(54) DEVICE FOR DETERMINING A FLOW-VELOCITY-DEPENDENT VARIABLE OF A FREE-FLOWING MEDIUM

(71) Applicant: Endress+Hauser Flowtec AG, Reinach (CH)

(72) Inventors: Christof Huber, Bern (CH); Raphael Kuhnen, Schliengen (DE); Anne Habermehl, Erding (DE); Wolfgang Drahm, Freising (DE)

(21) Appl. No.: 18/689,782

(22) PCT Filed: Aug. 10, 2022
(86) PCT No.: PCT/EP2022/072434

§ 371 Date: Mar. 6, 2024

(30) Foreign Application Priority Data
Sep. 6, 2021 (DE) 10 2021 122 992.8

(51) Int. Cl. G01F 1/58; G01F 15/061

(52) U.S. Cl. CPC G01F 1/58; G01F 15/061

(57) ABSTRACT

The present disclosure relates to a device for determining a flow-velocity-dependent variable of a medium in a guide body, where the guide body includes a magnetic-field-generating device generating a first magnetic field separating movable charge carriers in the medium, and a magnetic-field-sensitive measuring assembly designed to provide a measurement signal and which correlates with a change in and/or a strength of a second magnetic field generated by the movable charge carriers. The magnetic field-sensitive measuring assembly comprises a magnetic-field-sensitive measuring device that comprises an optically excitable material. The magnetic-field-sensitive measuring assembly has an optical excitation unit for optically exciting the magnetic-field-sensitive measuring device and an optical detection unit for detecting the measurement signal. An evaluation unit is designed to determine the flow-velocity-dependent variable of the medium at least the measurement signal provided by the magnetic-field-sensitive assembly and the conductivity of the medium.

The invention relates to a device for determining a flow-velocity-dependent variable of a free-flowing medium.

Magneto-inductive flow measuring devices are used for determining the flow rate and the volumetric flow of a flowing medium in a pipeline. A distinction is made here between in-line magneto-inductive flow meters and magneto-inductive flow measuring probes, which usually are inserted into a lateral opening of a pipeline. A magneto-inductive flow meter has a device for generating a magnetic field, which generates a magnetic field perpendicularly to the direction of flow of the free-flowing medium. Single coils are typically used for this purpose. In order to realize a predominantly homogeneous magnetic field, pole shoes are additionally formed and attached such that the magnetic field lines run over the entire tube cross-section substantially perpendicularly to the transverse axis or in parallel to the vertical axis of the measuring tube. In addition, a magneto-inductive flow meter has a measuring tube on which the device for generating the magnetic field is arranged. A measuring electrode pair in contact with the medium attached to the lateral surface of the measuring tube taps an electrical measurement voltage or potential difference which is applied perpendicularly to the direction of flow and to the magnetic field and occurs if a conductive medium flows in the direction of flow when the magnetic field is applied. Since, according to Faraday's law of induction, the tapped measurement voltage depends upon the velocity of the free-flowing medium, the flow rate and, with the inclusion of a known tube cross-section, the volumetric flow can be determined from the induced measurement voltage.

In contrast to a magneto-inductive flow meter, which comprises a measuring tube for conducting the medium with an attached device for generating a magnetic field penetrating the measuring tube and with measuring electrodes, magneto-inductive flow measuring probes are inserted with their usually circular cylindrical housings into a lateral opening of a tube line and fixed in a fluid-tight manner. A special measuring tube is no longer necessary. The measuring electrode assembly and coil assembly, mentioned in the introduction, on the lateral surface of the measuring tube are omitted and are replaced by a device for generating a magnetic field, which device is arranged in the interior of the housing and in direct proximity to the measuring electrodes and is designed such that an axis of symmetry of the magnetic field lines of the generated magnetic field perpendicularly intersects the front face or the face between the measuring electrodes. In the prior art, there are already a plurality of different magneto-inductive flow measuring probes.

Magneto-inductive flow measuring devices are often used in process and automation engineering for fluids, starting from an electrical conductivity of approximately 5 μS/cm. Corresponding flow measuring devices are sold by the applicant in a wide variety of embodiments for various fields of application—for example, under the name, PROMAG or MAGPHANT.

The invention is based upon the object of providing an alternative device for determining a flow-velocity-dependent variable of a free-flowing medium.

The object is achieved by the device according to claim 1.

The device according to the invention for determining a flow-velocity-dependent variable of a free-flowing and conductive medium in a guide body for guiding the medium, in particular in a measuring tube or a pipeline, comprises:
a magnetic-field-generating device for generating a first magnetic field which separates movable charge carriers in the medium;
a magnetic-field-sensitive measuring assembly, which is designed to provide a measurement signal, in particular a fluorescence signal, which correlates with a change in and/or a strength of a second magnetic field generated by the movable charge carriers,
   wherein the magnetic-field-sensitive measuring assembly comprises at least one magnetic-field-sensitive measuring device,
   wherein the at least one magnetic-field-sensitive measuring device comprises an optically excitable material,
   wherein the magnetic-field-sensitive measuring assembly has an optical excitation unit for optically exciting the magnetic-field-sensitive measuring device, in particular the optically excitable material, and an optical detection unit for detecting the measurement signal, in particular the fluorescence signal;
an evaluation unit, which is designed to determine the flow-velocity-dependent variable of the medium at least by means of the measurement signal provided by the magnetic-field-sensitive assembly, in particular the fluorescence signal, and a conductivity of the medium.

The conductivity of the medium flowing through can be determined and made available by a conductivity sensor also located on the measuring tube or pipeline. Alternatively—for example, for applications with a known and unchanging medium—the conductivity can be specified by the operator.

The magnetic-field-sensitive measuring device takes over the function of the measuring electrodes, which in conventional magnetic-inductive flow meters are either arranged on the outer surface of the guide body—for example, a carrier tube—or extend through openings in the guide body into the interior of the carrier tube and are therefore in contact with the medium. The measuring electrodes in conjunction with a measurement circuit are designed to measure an induced measurement voltage in the medium that is proportional to the flow velocity of the medium. The advantage over the second variant is that, on the one hand, no openings—and therefore potential leakage points—are required in the guide body and, on the other, wear is significantly reduced. The guide body can be made of an electrically insulating material or have electrical insulation—a so-called liner—attached to the inner lateral surface.

The evaluation unit comprises at least one electronic circuit, which is formed and designed to determine the flow-velocity-dependent variable of the medium at least by means of the measurement signal provided by the magnetic-field-sensitive assembly, in particular the fluorescence signal, which correlates with a change in and/or a strength of a second magnetic field generated by the movable charge carriers, and a conductivity of the medium. For this purpose, the electronic circuit can have electronic components such as passive components, energy sources, active components, integrated circuits, and/or embedded computer systems.

The first magnetic field generated by the magnetic-field-generating device at the position of the magnetic-field-sensitive measuring assembly can be determined and characterized by means of an empty pipe calibration carried out before the device is put into operation. Thus, this is known.

If a free-flowing medium through the guide body is present, the movable charge carriers experience a force perpendicular to the first magnetic field and the direction of flow, due to the generated first magnetic field. This leads to a separation of the charge carriers into two separate paths. These paths in turn generate a second magnetic field, which depends upon the flow velocity and the conductivity of the medium. The magnetic field actually present at the magnetic-field-sensitive measuring assembly, in particular at the respective magnetic-field-sensitive measuring device, is thus composed of the first magnetic field and the second magnetic field. If the conductivity of the medium and the first magnetic field generated by means of the magnetic-field-generating device are known, the contribution of the second magnetic field and thus also the flow-velocity-dependent variable of the medium can be determined.

Advantageous embodiment of the invention are the subject matter of the dependent claims.

One embodiment provides that the magnetic-field-sensitive measuring device comprise a crystal body with at least one vacancy center or a gas cell.

One embodiment provides that the crystal body comprise a diamond having at least one nitrogen-vacancy center, a silicon carbide having at least one silicon vacancy, or a hexagonal boron nitride having at least one vacancy color center.

One embodiment provides that the gas cell comprise at least one cell enclosing a gaseous alkali metal.

The device comprises an excitation unit for optically exciting the subunit, i.e., the optically excitable material or the crystal body or the gas cell, and a detection unit for detecting a fluorescence signal of the crystal body or the gas cell, which correlates with the magnetic field acting upon the magnetic-field-sensitive measuring device, in particular the optically excitable material. Optionally, filters and mirrors as well as further optical elements can be used to direct an excitation light to the crystal body or to the gas cell and/or the fluorescence signal towards the detection unit. The crystal body can optionally be subjected to a microwave signal, in particular a frequency-dependent microwave signal, which is generated by a microwave unit that is part of the magnetic-field-sensitive measuring unit or that can be integrated into the magnetic-field-sensitive measuring unit or formed as a separate unit.

One embodiment provides that the magnetic-field-generating device comprise at least one permanent magnet, in particular two permanent magnets, preferably arranged diametrically.

One embodiment provides that the magnetic field of the magnetic-field-generating device have a main axis Y,
wherein the guide body has a longitudinal axis Z,
wherein a transverse axis X runs perpendicular to the longitudinal axis Z and main axis Y,
wherein the transverse axis X and a reference axis A intersecting the magnetic-field-sensitive measuring device together span a center point angle α,
wherein the center point angle α is between 20° and 80°, in particular between 30° and 60° and preferably between 40° and 50°.

The advantage of this embodiment is that the smallest magnetic field changes in the absolute magnetic field present at the measuring position caused by the charge carriers in the free-flowing medium can be detected particularly well.

One embodiment provides that the magnetic-field-sensitive measuring assembly have at least two magnetic-field-sensitive measuring devices,
wherein the two magnetic-field-sensitive measuring devices are positioned symmetrically to the main axis Y.

One embodiment provides that the magnetic-field-sensitive measuring assembly have at least two magnetic-field-sensitive measuring devices,
wherein the two magnetic-field-sensitive measuring devices are positioned asymmetrically to the main axis Y.

One embodiment provides that the magnetic-field-generating device and/or the magnetic-field-sensitive measuring assembly be able to be attached to an outer lateral surface of the guide body in a mechanically separable manner.

Since the magnetic-field-sensitive measuring device does not necessarily have to be in contact with the medium, it is possible to realize a clamp-on device that can be attached to existing pipelines. This has the advantage that the devices can be mounted at the measuring points or devices can be replaced, without having to interrupt existing processes. A mechanically separable connection of the device to the guide body excludes a material-fit connection of individual components of the device according to the invention. In an advantageous embodiment, the magnetic-field-generating device and/or the magnetic-field-sensitive measuring assembly are connected to the guide body via a detachable clamp connection.

One embodiment provides that the device have a fastening device with which the magnetic-field-generating device and/or the magnetic-field-sensitive measuring assembly can be detachably fastened to the outer lateral surface.

One embodiment provides that the device have a housing,
wherein the housing is designed to be arranged in contact with the medium in an opening of the guide body,
wherein the magnetic-field-generating device, in particular the at least one permanent magnet, and the magnetic-field-sensitive measuring assembly are arranged in the housing.

This embodiment differs from the previous embodiment in that at least parts of the device, in particular the housing—in which the magnetic-field-generating device and the magnetic-field-sensitive measuring assembly are housed—are formed so as to come into contact with the medium. In this case, a housing is provided in which the magnetic-field-generating device and the magnetic-field-sensitive measuring assembly are housed. The housing protects them from the medium to be conveyed. This embodiment is similar to the magneto-inductive flow meter probe; see EP 0 892 251 A1. Such devices can be easily integrated into an existing pipeline with an opening in the lateral surface.

One embodiment provides that the housing have a front section, which intersects a main axis Y of the magnetic field,
wherein the magnetic-field-sensitive measuring assembly is arranged between the magnetic-field-generating device and the front section.

The invention is explained in greater detail with reference to the following figures. Shown are:

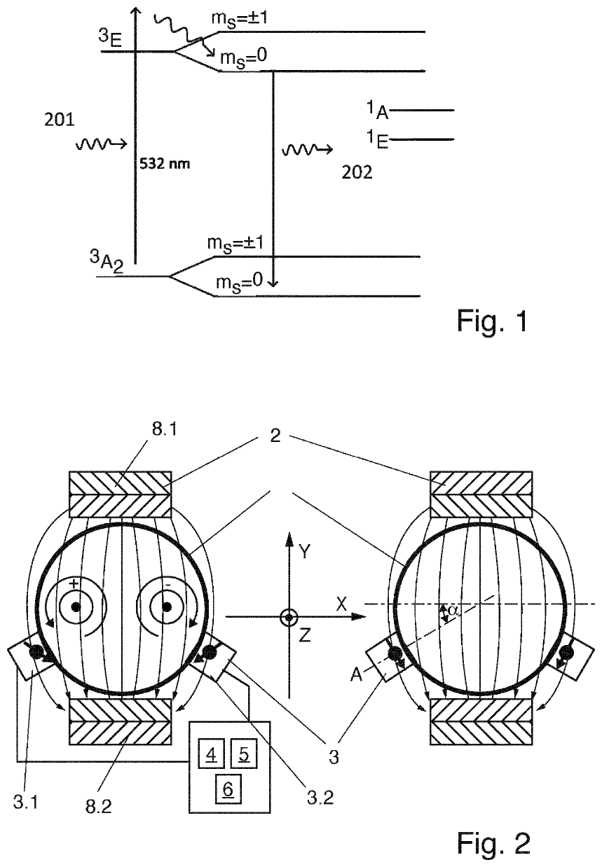

FIG. 1: a simplified energy diagram for a negatively charged NV center in the diamond;

FIG. 2: a simplified functional diagram of the measuring principle using an empty measuring tube (right) and a measuring tube that is flowed through (left);

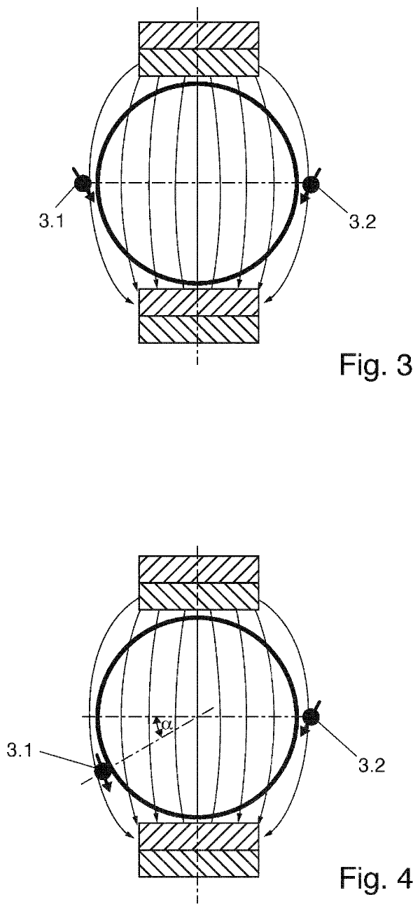

FIG. 3: an embodiment of the device according to the invention;

FIG. 4: a further embodiment of the device according to the invention;

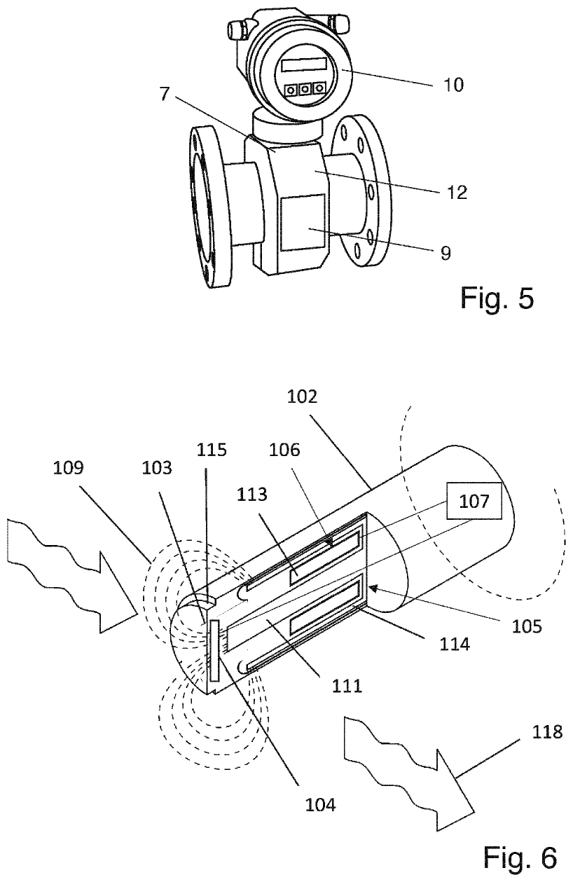

FIG. 5: a device according to the invention, which is formed as a clamp-on variant; and

FIG. 6: a device according to the invention, which is formed as a plug-in variant.

FIG. 1 shows a simplified energy diagram for a negatively charged NV center in a diamond to exemplify the excitation and fluorescence of a defect in a crystal body. The following considerations can be transferred to other crystal bodies having corresponding vacancies.

In the diamond, each carbon atom is typically covalently bonded to four further carbon atoms. A nitrogen vacancy center (NV center) consists of a vacancy in the diamond lattice, i.e., an unoccupied lattice site, and a nitrogen atom as one of the four neighboring atoms. In particular, the negatively charged NV⁻ centers are important for the excitation and evaluation of fluorescence signals. In the energy diagram of a negatively charged NV center, there is a triplet ground state 3A and an excited triplet state 3E, each of which has three magnetic substates ms=0, ±1. Furthermore, there are two metastable singlet states 1A and 1E between the ground state 3A and the excited state 3E.

Excitation light 201 from the green range of the visible spectrum, e.g., an excitation light 201 with a wavelength of 532 nm, excites an electron from the ground state 3A into a vibrational state of the excited state 3E, which returns to the ground state 3A by emitting a fluorescence photon 202 with a wavelength of 630 nm. An applied magnetic field with a magnetic field strength B leads to a splitting (Zeeman splitting) of the magnetic sub-states, so that the ground state consists of three, energetically separated sub-states, each of which can be excited. However, the intensity of the fluorescence signal is dependent upon the respective magnetic sub-state from which it was excited, so that the magnetic field strength B, for example, can be calculated using the Zeeman formula on the basis of the distance between the fluorescence minima. In the context of the present invention, further possibilities for evaluating the fluorescence signal are provided, such as the evaluation of the intensity of the fluorescent light, which is likewise proportional to the applied magnetic field. An electrical evaluation can in turn be done, for example, via a Photocurrent Detection of Magnetic Resonance (PDMR). In addition to these examples for evaluating the fluorescence signal, there are other possibilities which also fall within the scope of the present invention.

The excitation of gas cells is not explicitly shown, but the excitation of gas cells with light of a defined wavelength also leads to the excitation of an electron, wherein the emission of fluorescent light follows. For example, the intensity and/or the wavelength of the emitted fluorescent light is used to determine the magnetic field.

FIG. 2 shows a simplified functional diagram of the measuring principle using an empty device (right) and a device that is flowed through (left). The device according to the invention for determining a flow-velocity-dependent variable of a free-flowing medium in a guide body 1 for guiding the medium, in particular in a measuring tube or a pipeline, comprises a magnetic-field-generating device 2 for generating a first magnetic field separating movable charge carriers in the medium and a magnetic-field-sensitive measuring assembly, which is designed to provide a measurement signal, in particular a fluorescence signal, which correlates with a change in and/or a strength of a second magnetic field generated by the movable charge carriers. The magnetic-field-sensitive measuring assembly comprises at least one magnetic-field-sensitive measuring device 3 with an optically excitable material. Furthermore, the magnetic-field-sensitive measuring assembly 3 comprises an optical excitation unit 4 for optically exciting the magnetic-field-sensitive measuring device 3, in particular the optically excitable material, and an optical detection unit 5 for detecting the measurement signal, in particular the fluorescence signal. The magnetic-field-sensitive measuring device 3 comprises a crystal body with at least one vacancy center or a gas cell. If the magnetic-field-sensitive measuring device 3 comprises a crystal body, this comprises a diamond having at least one nitrogen-vacancy center, a silicon carbide having at least one silicon vacancy, or a hexagonal boron nitride having at least one vacancy color center. If the magnetic-field-sensitive measuring device 3 comprises a gas cell, it comprises a cell enclosing a gaseous alkali metal. An evaluation unit 6, which is also part of the device, is designed to determine the flow-velocity-dependent variable of the medium at least by means of the measurement signal, provided by the magnetic-field-sensitive assembly, and the conductivity of the medium. According to the illustrated embodiment, the magnetic-field-generating device 2 has two permanent magnets 8.1, 8.2, preferably arranged diametrically. Alternatively, the magnetic-field-generating device 2 can also have one or two diametrically arranged coils, which generate a time-varying or constant magnetic field. The generated first magnetic field of the magnetic-field-generating device 2 has a main axis Y. The guide body 1 has a longitudinal axis Z. The transverse axis X runs perpendicular to the longitudinal axis Z and main axis Y, which, together with a reference axis A intersecting the magnetic-field-sensitive measuring device 3, span a center point angle α. The center point angle α is between 20° and 80°, in particular between 30° and 60° and preferably between 40° and 50°. Even the smallest magnetic field changes caused by the separated charge carriers can be detected at this position. The illustrated embodiment has exactly two magnetic-field-sensitive measuring devices 3.1, 3.2, both of which are positioned symmetrically to the main axis Y. The two magnetic-field-sensitive measuring devices 3.1, 3.2 are designed to determine the magnetic field present at their mounting position. This is composed of the first magnetic field and the flow-velocity-dependent second magnetic field. If the first magnetic field is known—for example, from an empty pipe calibration—the second magnetic field and thus also the flow-velocity-dependent variable, in particular the flow velocity, the volume flow rate, and/or—if the mass density is known—the mass flow rate can be determined by means of the evaluation unit formed and designed for this purpose.

FIG. 3 shows a highly simplified representation of an embodiment of the device according to the invention, which differs from the embodiment of FIG. 2 substantially in the position of the magnetic-field-sensitive measuring devices 3.1, 3.2. The two magnetic-field-sensitive measuring devices 3.1, 3.2 are arranged diametrically on the outer wall of the carrier tube in such a way that they are intersected by the transverse axis X. At this point, the superposition of the first magnetic field and the second magnetic field, in particular the contribution of the second magnetic field to the magnetic field present at the measuring position, is particularly large. Due to the symmetrical assembly, in particular the mirror-symmetrical assembly of the magnetic-field-sensitive measuring devices 3.1, 3.2 relative to the main axis Y, the two measurement results can be compared in the presence of an axially symmetrical first magnetic field and an axially symmetrical flow profile, from which, for example, the passage of a magnetic foreign body or a foreign body that locally interferes with the conductivity of the medium can be deduced.

FIG. 4 also shows a further embodiment of the device according to the invention, which differs from the embodiments of FIG. 2 and FIG. 3 essentially in its positioning on the outer wall of the guide body. The two magnetic-field-sensitive measuring devices 3.1, 3.2 are positioned asymmetrically to the main axis Y. The transverse axis X and the reference axis running through the first magnetic-field-sensitive measuring device 3.1 have a center point angle α, which is between 20° and 80°, in particular between 30° and 60° and preferably between 40° and 50°. The second magnetic-field-sensitive measuring device 3.2 is positioned on the transverse axis X. This embodiment has the advantage that the absolute contribution of the second magnetic field to the magnetic field determined at the measuring position and, at the same time, the magnetic field change caused by the second magnetic field are available for determining the flow-velocity-dependent variable.

FIG. 5 shows a device according to the invention, which is formed as a clamp-on variant. For this purpose, the magnetic-field-generating device 2 and/or the magnetic-field-sensitive measuring assembly, in particular the housing 12 enclosing the magnetic-field-generating device 2 and/or the magnetic-field-sensitive measuring assembly, can be attached to an outer lateral surface of the guide body 1 in a mechanically separable manner. A fastening device 9 is designed to detachably fasten the magnetic-field-generating device 2 and/or the magnetic-field-sensitive measuring assembly to the outer lateral surface of the field guide body, in particular in a form-fitting and/or force-fitting manner. The evaluation unit can be arranged in the housing 12 or in the measuring transducer 10.

FIG. 6 shows a device according to the invention, which is formed as a plug-in variant. The device for determining the flow-velocity-dependent size of the free-flowing medium in the guide body comprises a magnetic-field-generating device 105 for generating a first magnetic field that separates movable charge carriers in the medium. For this purpose, the magnetic-field-generating device 105 has a coil assembly 106-in this case, a coil 113, a coil core 111, and a field return body 114. The housing 102 is sealed in a medium-tight manner with a front body 115 arranged in the end section 103. Thus, it can be positioned in an opening in the guide body, in particular in a pipeline, in contact with the medium.

A magnetic-field-sensitive measuring assembly with precisely one magnetic-field-sensitive measuring device 104, which is designed to provide a measurement signal, in particular a fluorescence signal, which correlates with a change in and/or a strength of a second magnetic field generated by the movable charge carriers, is arranged between the front body 115 or the front section 103 and the coil core 111. The magnetic-field-sensitive measuring device comprises an optically excitable material which is optically excitable via an optical excitation unit, and an optical detection unit for detecting a fluorescence signal emitted by the optically excitable material. An evaluation unit 107 is designed to determine the flow-velocity-dependent variable of the medium at least by means of the measurement signal, provided by the magnetic-field-sensitive assembly, and the conductivity of the medium. The evaluation unit can be arranged in the housing 102 or in an external measuring sensor.

### LIST OF REFERENCE SIGNS

Guide body 1
Magnetic-field-generating device 2
Magnetic-field-sensitive measuring device 3
First magnetic-field-sensitive measuring device 3.1
Second magnetic-field-sensitive measuring device 3.2
Optical excitation unit 4
Optical detection unit 5
Evaluation unit 6
Housing 7
Permanent magnet 8
First permanent magnet 8.1
Second permanent magnet 8.2
Fastening device 9
Measuring transducer 10
Magneto-inductive flow measuring probe 101
Housing 102
End section 103
Magnetic-field-sensitive measuring assembly 104
Magnetic-field-generating device 105
Coil assembly 106
Evaluation unit 107
First magnetic field 109
Coil core 111
Coil 113
Field return body 114
Front body 115
Direction of flow of the medium 118

1-12. (canceled)

13. A device for determining a flow-velocity-dependent variable of a free-flowing medium in a guide body for guiding the medium, comprising:
a magnetic-field-generating device for generating a first magnetic field which separates movable charge carriers in the medium;
a magnetic-field-sensitive measuring assembly, which is designed to provide a measurement signal which correlates with a change in and/or a strength of a second magnetic field generated by the movable charge carriers,
wherein the magnetic-field-sensitive measuring assembly comprises at least one magnetic-field-sensitive measuring device,
wherein the at least one magnetic-field-sensitive measuring device comprises an optically excitable material,
wherein the magnetic-field-sensitive measuring assembly has an optical excitation unit for optically exciting the magnetic-field-sensitive measuring device, and an optical detection unit for detecting the measurement signal;
an evaluation unit, which is designed to determine the flow-velocity-dependent variable of the medium at least by means of the measurement signal, provided by the magnetic-field-sensitive assembly, and the conductivity of the medium.

14. The device according to claim 13,
wherein the magnetic-field-sensitive measuring device comprises a crystal body with at least one vacancy center or a gas cell.

15. The device according to claim 14,
wherein the crystal body comprises a diamond having at least one nitrogen vacancy center, a silicon carbide having at least one silicon vacancy, or a hexagonal boron nitride having at least one vacancy color center.

16. The device according to claim 14,
wherein the gas cell comprises at least one cell enclosing a gaseous alkali metal.

17. The device according to claim 13,
wherein the magnetic-field-generating device comprises at least one permanent magnet.

18. The device according to claim 17,
wherein the magnetic field of the magnetic-field-generating device has a main axis Y,
wherein the guide body has a longitudinal axis Z,
wherein a transverse axis X runs perpendicular to the longitudinal axis Z and main axis Y,
wherein the transverse axis X and a reference axis A intersecting the magnetic-field-sensitive measuring device (3) together span a center point angle α,
wherein the center point angle α is between 20° and 80°.

19. The device according to claim 18,
wherein the magnetic-field-sensitive measuring assembly has at least two magnetic-field-sensitive measuring devices,
wherein the two magnetic-field-sensitive measuring devices are positioned symmetrically to the main axis Y.

20. The device according to claim 18,
wherein the magnetic-field-sensitive measuring assembly has at least two magnetic-field-sensitive measuring devices,
wherein the two magnetic-field-sensitive measuring devices are positioned asymmetrically to the main axis Y.

21. The device according to claim 13,
wherein the magnetic-field-generating device and/or the magnetic-field-sensitive measuring assembly can be attached to an outer lateral surface of the guide body in a mechanically separable manner.

22. The device according to claim 21,
wherein the device has a fastening device with which the magnetic-field-generating device and/or the magnetic-field-sensitive measuring assembly can be detachably fastened to the outer lateral surface.

23. The device according to claim 13,
wherein the device has a housing,
wherein the housing is designed to be arranged in contact with the medium in an opening of the guide body,
wherein the magnetic-field-generating device, in particular the at least one permanent magnet, and the magnetic-field-sensitive measuring assembly are arranged in the housing.

24. The device according to claim 23,
wherein the housing has a front section, which intersects a main axis Y of the magnetic field,
wherein the magnetic-field-sensitive measuring assembly is arranged between the magnetic-field-generating device and the front section.
